(19) United States
(12) Patent Application Publication
(10) Pub. No.: US 2026/0223600 A1
(43) Pub. Date: Jul. 30, 2026

(54) Magnetic Tunnel Junction Structure

(71) Applicant: ZHEJIANG HIKSTOR TECHNOLOGY CO., LTD., Hangzhou, Zhejiang (CN)

(72) Inventors: Dinggui ZENG, Hangzhou, Zhejiang (CN); Ruofei CHEN, Hangzhou, Zhejiang (CN); Fantao MENG, Hangzhou,Zhejiang (CN); Guchang HAN, Hangzhou,Zhejiang (CN)

(21) Appl. No.: 19/143,373

(22) PCT Filed: Dec. 7, 2023
(86) PCT No.: PCT/CN2023/137148

§ 371 Date: Jun. 26, 2025

(30) Foreign Application Priority Data
Dec. 29, 2022 (CN) 202211711818.5

(51) Int. Cl. H10N 50/10; H10B 61/00; H10N 50/85

(52) U.S. Cl. CPC H10N 50/10; H10B 61/00; H10N 50/85

(57) ABSTRACT

The present disclosure provides a magnetic tunnel junction structure. The magnetic tunnel junction structure includes a reference layer, a barrier layer and a free layer, which are stacked, wherein the free layer includes: a first free layer, disposed on a side of the barrier layer that is away from the reference layer, a material of the first free layer including a first cobalt-ferrum boride; an isolation coupling layer, disposed on a side of the first free layer that is away from the barrier layer, a material of the isolation coupling layer including at least one nonmagnetic metal; and a second free layer, disposed on a side of the isolation coupling layer that is away from the first free layer, a material of the second free layer including a second cobalt-ferrum boride, and the second cobalt-ferrum boride and/or the first cobalt-ferrum boride being doped with at least one nonmagnetic metal.

### CROSS-REFERENCE TO RELATED APPLICATION

The disclosure claims the priority of Chinese Patent Application No. 202211711818.5, filed with the China National Intellectual Property Administration on Dec. 29, 2022 and entitled “Magnetic Tunnel Junction Structure”, which is incorporated in its entirety herein by reference.

### TECHNICAL FIELD

The present disclosure relates to the technical field of memories, and in particular to a magnetic tunnel junction structure.

### BACKGROUND

A magnetic random access memory (MRAM) serves as a free layer for storing information in a magnetic tunnel junction (MTJ) having perpendicular magnetic anisotropy (PMA), and has two magnetization directions in a vertical direction, that is, upward and downward, which respectively correspond to “0” and “1” or “1” and “0” in a binary system, in practical applications, when reading information or being idle, the magnetization directions of the free layer remain unchanged; and during a writing process, if a signal different from an existing state is input, the magnetization directions of the free layer will be flipped in the vertical direction by 180 degrees. The capability of keeping the magnetization directions of the free layer of the magnetic random access memory unchanged is called a data storage capability or a thermal stability factor, the requirements in different application cases are different, for a typical non-volatile memory (NVM), the data storage capability is required to store data for 10 years under the condition of 125° C., and the data storage capability or thermal stability may be reduced in the case of overturning of an external magnetic field, thermal disturbance, current disturbance, or multiple read-write operations.

In order to improve the storage density of the magnetic random access memory, in recent years, the critical dimension of the magnetic tunnel junction becomes smaller and smaller. When the dimension is further reduced, it is discovered that the thermal stability factor (∇) of the magnetic tunnel junction deteriorates sharply. In order to improve the thermal stability factor (∇) of an ultra-small MRAM unit device, the effective perpendicular anisotropy energy density may be increased by means of a series of measures, for example, reducing the thickness of the free layer, adding a material with a low saturation magnetization rate into the free layer or changing the free layer into the material with the low saturation magnetization rate, so as to maintain a higher thermal stability factor (∇), but the tunnel magnetoresistance ratio (TMR) of the magnetic tunnel junction will be reduced, thereby increasing the error rate of a read operation of the memory.

### SUMMARY

According to some embodiments of the present disclosure, a magnetic tunnel junction structure is provided, including a reference layer, a barrier layer and a free layer, which are stacked, wherein the free layer includes: a first free layer, disposed on a side of the barrier layer that is away from the reference layer, the material of the first free layer including a first cobalt-ferrum boride; an isolation coupling layer, disposed on a side of the first free layer that is away from the barrier layer, the material of the isolation coupling layer including at least one nonmagnetic metal; and a second free layer, disposed on a side of the isolation coupling layer that is away from the first free layer, the material of the second free layer including a second cobalt-ferrum boride, and the second cobalt-ferrum boride is doped with at least one nonmagnetic metal, or the first cobalt-ferrum boride is doped with at least one nonmagnetic metal, or the second cobalt-ferrum boride and the first cobalt-ferrum boride is doped with at least one nonmagnetic metal.

Further, the material of the isolation coupling layer includes a first nonmagnetic metal, the first cobalt-ferrum boride is doped with a second nonmagnetic metal, and the second cobalt-ferrum boride is doped with a third nonmagnetic metal.

Further, a type of the second nonmagnetic metal is the same as a type of the third nonmagnetic metal.

Further, the type of the second nonmagnetic metal and a type of the third nonmagnetic metal are the same as the type of the first nonmagnetic metal.

Further, the first nonmagnetic metal, the second nonmagnetic metal and the third nonmagnetic metal independently include any one or more of hafnium, zirconium, tantalum, molybdenum, tungsten, iridium, ruthenium, rhodium, and magnesium.

Further, a doping concentration of the second nonmagnetic metal and a doping concentration of the third nonmagnetic metal independently satisfy 5%-25%.

Further, a doping concentration of the second nonmagnetic metal is equal to a doping concentration of the third nonmagnetic metal.

Further, a thickness of the isolation coupling layer is in a range of 0.2-2.0 Å.

Further, the magnetic tunnel junction structure includes a plurality of groups of stacked structures, which are stacked, and each of group of stacked structures includes one first free layer, one isolation coupling layer, and one second free layer.

Further, a thickness of the isolation coupling layer is greater than a thickness of the first free layer or a thickness of the second free layer.

### BRIEF DESCRIPTION OF THE DRAWINGS

The drawings, which constitute a part of the present disclosure, are used to provide a further understanding of the present disclosure, and illustrative embodiments of the present disclosure and descriptions thereof are used to explain the present disclosure and do not constitute improper limitations to the present disclosure. In the drawings:

FIG. 1 illustrates a schematic diagram of a sectional structure of a magnetic tunnel junction structure according to an embodiment of the present disclosure;

FIG. 2 illustrates a schematic diagram of a sectional structure of a first example of a free layer shown in FIG. 1;

FIG. 3 illustrates a schematic diagram of a sectional structure of a second example of the free layer shown in FIG. 1;

FIG. 4 illustrates a schematic diagram of a sectional structure of a third example of the free layer shown in FIG. 1;

FIG. 5 illustrates a schematic diagram of a sectional structure of a fourth example of the

FIG. 6 illustrates a schematic diagram of a sectional structure of a fifth example of the free layer shown in FIG. 1;

FIG. 7 illustrates a schematic diagram of a sectional structure of a sixth example of the free layer shown in FIG. 1;

FIG. 8 illustrates a schematic diagram of a sectional structure of a seventh example of the free layer shown in FIG. 1;

FIG. 9 illustrates a schematic diagram of a sectional structure of an eighth example of the free layer shown in FIG. 1; and

FIG. 10 illustrates a schematic diagram of a sectional structure of a ninth example of the free layer shown in FIG. 1.

The above drawings include the following reference signs:
10. substrate; 20. reference layer; 30. barrier layer; 40. free layer; 50. cover layer; 60. first free layer; 70. isolation coupling layer; 80. second free layer.

### DETAILED DESCRIPTION OF THE EMBODIMENTS

It should be noted that, in the case of no conflict, embodiments in the present disclosure and features in the embodiments may be combined with each other. The present disclosure will be described in detail below with reference to the drawings and in combination with the embodiments.

In order to enable those skilled in the art to better understand the solutions of the present disclosure, the technical solutions in the embodiments of the present disclosure will be clearly and completely described below in combination with the drawings in the embodiments of the present disclosure. Apparently, the embodiments described below are merely a part, but not all, of the embodiments of the present disclosure. All of other embodiments, obtained by those ordinary skilled in the art based on the embodiments in the present disclosure without any creative effort, fall into the protection scope of the present disclosure.

It should be noted that, the terms “first” and “second” and the like in the specification, claims and the above drawings of the present disclosure are used for distinguishing similar objects, and are not necessarily used for describing a specific sequence or precedence order. It should be understood that data used in this way may be interchanged under appropriate circumstances, so that the embodiments of the present disclosure described herein may be implemented. In addition, the terms “including”, “having” and any variations thereof are intended to cover non-exclusive inclusions, for example, processes, methods, systems, products or devices including a series of steps or units are not necessarily limited to those clearly listed steps or units, but may include other steps or units that are not clearly listed or are inherent to these processes, methods, products or devices.

As mentioned in the background, in order to improve the storage density of a magnetic random access memory, in recent years, the critical dimension of a magnetic tunnel junction becomes smaller and smaller, however, when the dimension is further reduced, it is discovered that the thermal stability factor (∇) of the magnetic tunnel junction deteriorates sharply.

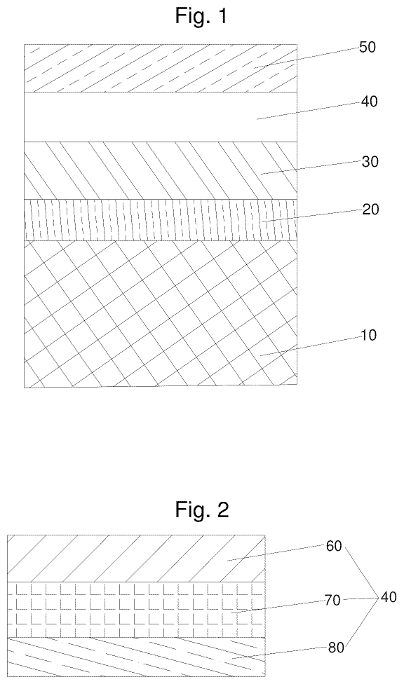

In order to solve the above technical problem, according to one embodiment of the present disclosure, a magnetic tunnel junction structure is provided. As shown in FIG. 1, the magnetic tunnel junction structure includes a reference layer 20, a barrier layer 30, a free layer 40 and a cover layer 50, which are stacked on a substrate 10. As shown in FIG. 2, the free layer 40 includes a first free layer 60, an isolation coupling layer 70, and a second free layer 80, wherein the first free layer 60 is disposed on the side of the barrier layer 30 that is away from the reference layer 20, and the material of the first free layer 60 includes a first cobalt-ferrum boride; the isolation coupling layer 70 is disposed on the side of the first free layer 60 that is away from the barrier layer 30, and the material of the isolation coupling layer 70 includes at least one nonmagnetic metal; and the second free layer 80 is disposed on the side of the isolation coupling layer 70 that is away from the first free layer 60, the material of the second free layer 80 includes a second cobalt-ferrum boride, and the first cobalt-ferrum boride and/or the second cobalt-ferrum boride is doped with at least one nonmagnetic metal.

By using the above magnetic tunnel junction structure, thin film materials of the first free layer 60 and the second free layer 80 include the cobalt-ferrum borides, and the cobalt-ferrum borides have the properties of small coercive forces, high saturation magnetization intensities, low attenuation factors α, and the like; meanwhile, since the first cobalt-ferrum boride and/or the second cobalt-ferrum boride is doped with at least one nonmagnetic metal, the nonmagnetic metal can not only improve the resistance of the first cobalt-ferrum boride and/or the second cobalt-ferrum boride, but can also improve the thermal stability and the oxidation resistance of the first cobalt-ferrum boride; and further, since the first cobalt-ferrum boride and the nonmagnetic metal are mutually solid-soluble, the mechanical strength, the thermal stability and the oxidation resistance may also be improved by solid solution, so that the magnetic anisotropy of the magnetic tunnel junction is enhanced, and thus improving the information writing capability of a corresponding device with the magnetic tunnel junction structure.

In the above magnetic tunnel junction structure of the present embodiment, the material of the isolation coupling layer 70 includes a first nonmagnetic metal, since the magnetic coupling strength of a single-layer cobalt-ferrum boride is weaker, by adding one isolation coupling layer made of the nonmagnetic metal between the first free layer and the second free layer, atoms in the isolation coupling layer may cause inter-layer charge transfer, so that the inter-layer magnetic coupling is significantly enhanced, and the magnetic anisotropy of the magnetic tunnel junction is enhanced.

In some optional implementations, the material of the first free layer 60 includes a second nonmagnetic metal doped in the first cobalt-ferrum boride.

In the above implementation, the nonmagnetic metal can not only improve the resistance of the first cobalt-ferrum boride serving as the first free layer 60, but can also improve the thermal stability and the oxidation resistance of the first cobalt-ferrum boride; and further, since the first cobalt-ferrum boride and the nonmagnetic metal are mutually solid-soluble, the mechanical strength, the thermal stability and the oxidation resistance can be improved, and thus the magnetic anisotropy of the magnetic tunnel junction is enhanced.

In some optional implementations, the material of the second free layer 80 includes a third nonmagnetic metal doped in the second cobalt-ferrum boride.

In the above implementation, similarly, the nonmagnetic metal can not only improve the resistance of the second cobalt-ferrum boride serving as the second free layer 80, but can also improve the thermal stability and the oxidation resistance of the second cobalt-ferrum boride; and further, since the second cobalt-ferrum boride and the nonmagnetic metal are mutually solid-soluble, the mechanical strength, the thermal stability and the oxidation resistance may also be improved by solid solution, and thus the magnetic anisotropy of the magnetic tunnel junction is enhanced.

In some optional implementations, the materials of the isolation coupling layer 70, the first free layer 60 and the second free layer 80 include nonmagnetic metals. Specifically, the material of the isolation coupling layer 70 includes the first nonmagnetic metal, the first free layer 60 further includes the second nonmagnetic metal doped in the first cobalt-ferrum boride, and the second free layer 80 further includes the third nonmagnetic metal doped in the second cobalt-ferrum boride. The types of the first nonmagnetic metal, the second nonmagnetic metal and the third nonmagnetic metal may be the same or different.

Exemplarily, as shown in FIG. 2, the material of the first free layer 60 includes a cobalt-ferrum boride CoFeB, the isolation coupling layer 70 is a nonmagnetic metal layer, and the material of the second free layer 80 includes an alloy CoFeBX₁ of a nonmagnetic metal X₁ and the cobalt-ferrum boride CoFeB. The isolation coupling layer 70 facilitates the regulation and control effect of an electric field at the magnetic tunnel junction for the magnetic anisotropy, and the atoms in the isolation coupling layer 70 may cause inter-layer charge transfer, so that the inter-layer magnetic coupling is significantly enhanced, and the magnetic anisotropy of the magnetic tunnel junction is enhanced; meanwhile, the nonmagnetic metal X₁ can not only improve the diffusion resistance of the cobalt-ferrum boride in the second free layer 80, but can also improve the thermal stability and the oxidation resistance of the cobalt-ferrum boride; and moreover, since the cobalt-ferrum boride and the nonmagnetic metal are mutually solid-soluble, the mechanical strength, the thermal stability and the oxidation resistance may also be improved by solid solution, so that the magnetic anisotropy of the magnetic tunnel junction is enhanced.

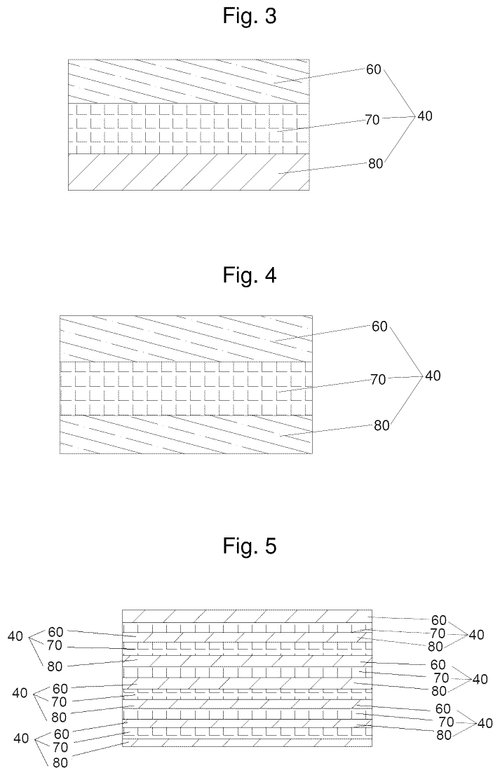

In another example, as shown in FIG. 3, the material of the first free layer 60 includes an alloy CoFeBX₂ of a nonmagnetic metal X₂ and the cobalt-ferrum boride CoFeB, the isolation coupling layer 70 is a nonmagnetic metal layer, and the material of the second free layer 80 includes the cobalt-ferrum boride. The isolation coupling layer 70 facilitates the regulation and control effect of the electric field at the magnetic tunnel junction for the magnetic anisotropy, and the atoms in the isolation coupling layer 70 may cause inter-layer charge transfer, so that the inter-layer magnetic coupling is significantly enhanced, and the magnetic anisotropy of the magnetic tunnel junction is enhanced; meanwhile, the nonmagnetic metal X₂ can not only improve the diffusion resistance of the second cobalt-ferrum boride in the first free layer 60, but can also improve the thermal stability and the oxidation resistance of the cobalt-ferrum boride; and moreover, since the cobalt-ferrum boride and the nonmagnetic metal are mutually solid-soluble, the mechanical strength, the thermal stability and the oxidation resistance may also be improved by solid solution, so that the magnetic anisotropy of the magnetic tunnel junction is enhanced.

In another example, as shown in FIG. 4, the material of the first free layer 60 includes an alloy CoFeBX₃ of a nonmagnetic metal X₃ and the cobalt-ferrum boride CoFeB, the isolation coupling layer 70 is a nonmagnetic metal layer, and the material of the second free layer 80 includes an alloy CoFeBX₄ of a nonmagnetic metal X₄ and the cobalt-ferrum boride CoFeB. Similarly, the isolation coupling layer 70 facilitates the regulation and control effect of the electric field at the magnetic tunnel junction for the magnetic anisotropy, and the atoms in the isolation coupling layer 70 may cause inter-layer charge transfer, so that the inter-layer magnetic coupling is significantly enhanced, and the magnetic anisotropy of the magnetic tunnel junction is enhanced; meanwhile, the nonmagnetic metals X₃ and X₄ respectively improve the diffusion resistance of the cobalt-ferrum borides in the first free layer 60 and the second free layer 80, and also improve the thermal stability and the oxidation resistance of the cobalt-ferrum borides; and moreover, since the cobalt-ferrum borides and the nonmagnetic metal are mutually solid-soluble, the mechanical strength, the thermal stability and the oxidation resistance may also be improved by solid solution, so that the magnetic anisotropy of the magnetic tunnel junction is enhanced.

In some optional implementations, the type of the second nonmagnetic metal is the same as the type of the third nonmagnetic metal.

In the above implementation, since the first free layer 60 is doped with the second nonmagnetic metal, and the second free layer 80 is doped with the third nonmagnetic metal, the resistances of the first free layer 60 and the second free layer 80 are both improved, and the thermal stability and the oxidation resistance of the first free layer 60 and the second free layer 80 are improved. Further, since the type of the second nonmagnetic metal is the same as the type of the third nonmagnetic metal, in a production process, the complexity of the process can be reduced, and process flows can be reduced.

Further, the types of the first cobalt-ferrum boride of the first free layer 60 and the second cobalt-ferrum boride of the second free layer 80 may be the same or different, wherein the material compositions of the first free layer 60 and the second free layer 80 may both be a cobalt-ferrum-boron alloy, or the material composition of the first free layer 60 may be the cobalt-ferrum-boron alloy, and the material composition of the second free layer 80 may be a cobalt-ferrum boride doped with the third nonmagnetic metal, or the material composition of the first free layer 60 may be a cobalt-ferrum boride doped with the second nonmagnetic metal, and the material composition of the second free layer 80 may be the cobalt-ferrum-boron alloy. Further, the content of each element in the cobalt-ferrum boride constituting the first free layer 60 and the content of the corresponding element in the cobalt-ferrum boride constituting the second free layer 80 may be the same or different.

In some optional implementations, a doping concentration of the second nonmagnetic metal and a doping concentration of the third nonmagnetic metal independently satisfy 5%-25%.

In the above implementation, as the dosage of the nonmagnetic metal, when a doping content of the second nonmagnetic metal exceeds 25%, the saturation magnetization of the first cobalt-ferrum boride of the first free layer 60 may be reduced, and similarly, when the doping content of the third nonmagnetic metal exceeds 25%, the saturation magnetization of the second nonmagnetic metal of the second free layer 80 may be reduced, therefore it is preferred that the doping content of the second nonmagnetic metal in the first free layer 60 and the doping content of the third nonmagnetic metal in the second free layer 80 independently satisfy 5%-25%, thereby ensuring the saturation magnetization intensities of the free layers while improving the mechanical strength, the thermal stability and the oxidation resistance of the free layers.

Optionally, the doping concentration of the second nonmagnetic metal and the doping concentration of the third nonmagnetic metal independently satisfy 5%-25%.

In some optional implementations, the doping concentration of the second nonmagnetic metal is equal to the doping concentration of the third nonmagnetic metal.

In the above implementation, in order to reduce the complexity and difficulty of the process, it is generally set that the doping content of the second nonmagnetic metal doped in the first cobalt-ferrum boride of the first free layer 60 is the same as the doping content of the third nonmagnetic metal doped in the second cobalt-ferrum boride of the second free layer 80, so that the doping can be completed by using the same process step, thereby saving the process time, greatly improving the working efficiency of the production process, and facilitating mass production of the product.

In some optional implementations, the thickness of the isolation coupling layer 70 satisfies 0.2-2.0 Å.

In the above implementation, in order to enhance the magnetic coupling strength of the first cobalt-ferrum boride of the first free layer 60 and the second cobalt-ferrum boride of the second free layer 80, the thickness of the isolation coupling layer 70 is set to be 0.2-2.0 Å, so that the atoms in the isolation coupling layer 70 can cause interlayer charge transfer, therefore the interlayer magnetic coupling is significantly enhanced, and the magnetic anisotropy of the magnetic tunnel junction is enhanced.

In some optional implementations, the magnetic tunnel junction structure includes a plurality of groups of stacked structures, which are stacked, and each of group of stacked structures includes one first free layer 60, one isolation coupling layer 70, and one second free layer 80.

In the above implementation, since the thickness of each thin film layer of the magnetic tunnel junction is relatively small, by using the multi-layer stacked structure including the first free layer 60, the isolation coupling layer 70 and the second free layer 80, the magnetic coupling strength between the layers of thin films can be enhanced, thereby achieving the purpose of enhancing the magnetic anisotropy of the magnetic tunnel junction.

Optionally, the material composition of the first free layer 60 in each stacked structure may be the first cobalt-ferrum boride and may also be the alloy of the second nonmagnetic metal and the first cobalt-ferrum boride, the material composition of the second free layer 80 in each stacked structure may be the second cobalt-ferrum boride and may also be the alloy of the third nonmagnetic metal and the second cobalt-ferrum boride, and the doping content of the second nonmagnetic metal in the first free layer 60 and the doping content of the third nonmagnetic metal in the second free layer 80 may be the same or different.

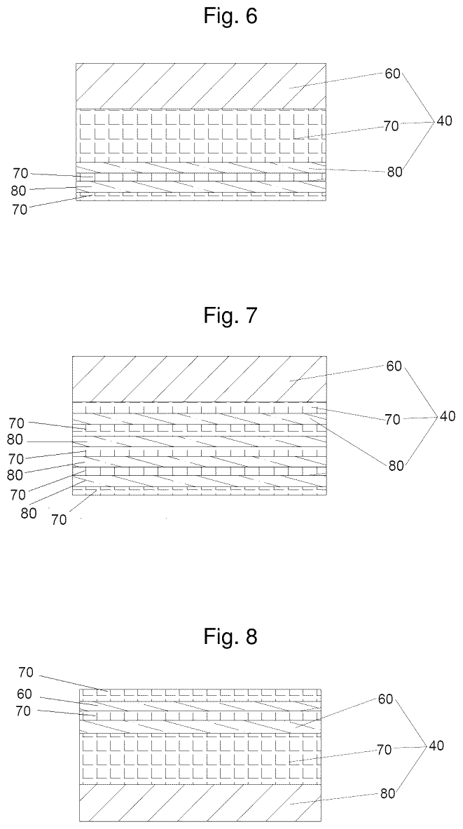

Exemplarily, each stacked structure constituting a multi-layer stacked structure includes the first free layer 60, the isolation coupling layer 70 and the second free layer 80, the material composition of the first free layer 60 is an alloy of the first cobalt-ferrum boride, the material composition of the isolation coupling layer 70 is a first nonmagnetic metal layer, and the material composition of the second free layer 80 is an alloy of the third nonmagnetic metal and the second cobalt-ferrum boride. Further, in another example, as shown in FIG. 5, in each stacked structure, the material composition of the first free layer 60 is the first cobalt-ferrum boride, the material composition of the isolation coupling layer 70 is the first nonmagnetic metal layer, the material composition of the second free layer 80 is the second cobalt-ferrum boride, and the first free layers 60 and the second free layers 80 in two adjacent layers of stacked structures together form the first free layer 60 or the second free layer 80 in each stacked structure. That is, one stacked structure has a material layer in common with another stack that serves as a first free layer 60 and a second free layer 80, respectively. For example, the multi-layer stacked structure comprises a first stacked structure, a second stacked structure and a third stacked structure, wherein a second free layer 80 in the first stacked structure and a first free layer 60 in the second stacked structure are a common material layer, and a second free layer 80 in the second stacked structure and a first free layer 60 in the third stacked structure are common material layers. Further, in another example, as shown in FIG. 6, each of the first free layer 60 and the isolation coupling layer 70 is an independent layer of thin film, and a multi-layer alternating stacked structure may also be another isolation coupling layer 70 and the second free layer 80; or, in another example, as shown in FIG. 7, the first free layer 60 is an independent layer of thin film, the isolation coupling layer 70 and the second free layer 80 may further constitute a multi-layer alternating stacked structure, and the number of the stacked structures in the multi-layer alternating stacked structure is greater than or equal to 2 and less than or equal to 12, thereby facilitating the regulation and control effect of the electric field at the magnetic tunnel junction for the magnetic anisotropy, and the atoms in the isolation coupling layer 70 may cause inter-layer charge transfer, so that the inter-layer magnetic coupling is significantly enhanced, and the magnetic anisotropy of the magnetic tunnel junction is enhanced.

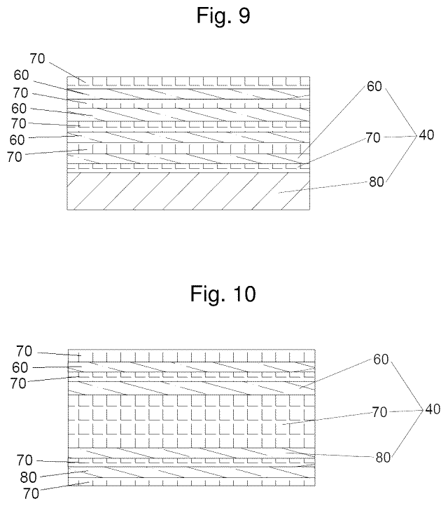

Exemplarily, each stacked structure constituting the multi-layer stacked structure includes the first free layer 60, the isolation coupling layer 70 and the second free layer 80, the material composition of the first free layer 60 is the alloy of the second nonmagnetic metal and the first cobalt-ferrum boride, the material composition of the isolation coupling layer 70 is the first nonmagnetic metal layer, and the material composition of the second free layer 80 is the second cobalt-ferrum boride. Further, in another example, as shown in FIG. 8, each of the isolation coupling layer 70 and the second free layer 80 is an independent layer of thin film, and the multi-layer alternating stacked structure may also be another isolation coupling layer 70 and the first free layer 60; or, in another example, as shown in FIG. 9, the second free layer 80 is an independent layer of thin film, the isolation coupling layer 70 and the first free layer 60 may further constitute a multi-layer alternating stacked structure, and the number of the stacked structures in the multi-layer alternating stacked structure is greater than or equal to 2 and less than or equal to 12, thereby facilitating the regulation and control effect of the electric field at the magnetic tunnel junction for the magnetic anisotropy, and the atoms in the isolation coupling layer 70 may cause inter-layer charge transfer, so that the inter-layer magnetic coupling is significantly enhanced, and the magnetic anisotropy of the magnetic tunnel junction is enhanced.

Exemplarily, each stacked structure constituting the multi-layer stacked structure includes the first free layer 60, the isolation coupling layer 70 and the second free layer 80, the material composition of the first free layer 60 is the alloy of the second nonmagnetic metal and the first cobalt-ferrum boride, the material composition of the isolation coupling layer 70 is the first nonmagnetic metal layer, and the material composition of the second free layer 80 is the alloy of the third nonmagnetic metal and the second cobalt-ferrum boride. Further, in another example, as shown in FIG. 10, the isolation coupling layer 70 is an independent layer of thin film, a multi-layer first alternating stacked structure may also be the first free layer 60 and another isolation coupling layer 70, and the second free layer 80 and another isolation coupling layer 70 constitute a second alternating stacked structure, the number of the stacked structures in the first alternating stacked structure is greater than or equal to 2 and less than or equal to 12, and the number of the stacked structures in the second alternating stacked structure is greater than or equal to 3 and less than or equal to 12, thereby facilitating the regulation and control effect of the electric field at the magnetic tunnel junction for the magnetic anisotropy, and the atoms in the isolation coupling layer 70 may cause inter-layer charge transfer, so that the inter-layer magnetic coupling is significantly enhanced, and the magnetic anisotropy of the magnetic tunnel junction is enhanced.

In some optional implementations, the thickness of the isolation coupling layer 70 is greater than the thickness of the first free layer 60 or the thickness of the second free layer 80.

In the above implementation, in order to significantly enhance the interlayer magnetic coupling and to enhance the magnetic anisotropy of the magnetic tunnel junction, the thickness of the isolation coupling layer 70 is usually set to be greater than the thickness of the first free layer 60 or the thickness of the second free layer 80, so as to achieve the above purpose, and to achieve the effects of well ensuring the saturation magnetization, the thermal stability and the stability tolerance.

In some optional implementations, the first nonmagnetic metal, the second nonmagnetic metal, and the third nonmagnetic metal independently include any one or more of zirconium, tantalum, molybdenum, tungsten, iridium, ruthenium, rhodium, and magnesium.

The nonmagnetic metals in the above implementations may be mutually solid-soluble to the first cobalt-ferrum boride in the first free layer 60 and the second cobalt-ferrum boride in the second free layer 80, so that the atomic ratio of the nonmagnetic metal to the magnetic metal is increased by solid solution, thereby blocking metal particles in the first free layer 60 and the second free layer 80 by using “large inclusion phases of nonmagnetic metals/magnetic metals” with high oxidation resistance and thermal stability, therefore the thermal stability and the oxidation resistance of the metal particles in the first free layer 60 and the second free layer 80 can be effectively improved. Further, the nonmagnetic metals further include a plurality of hafnium (Hf), zirconium (Zr), tantalum (Ta), molybdenum (Mo), tungsten (W), iridium (Ir), ruthenium (Ru), rhodium (Rh), and magnesium (Mg).

It can be seen from the above description that the above implementations of the present disclosure achieve the following technical effects:
1. since the thin film materials of the first free layer and the second free layer include the cobalt-ferrum borides, and meanwhile the first cobalt-ferrum boride and/or the second cobalt-ferrum boride is doped with at least one nonmagnetic metal, the magnetic anisotropy of the magnetic tunnel junction is enhanced, thereby improving the information writing capability of a corresponding device with the magnetic tunnel junction structure; and
2. since the magnetic coupling strength of the single-layer cobalt-ferrum boride is weaker, by adding one isolation coupling layer of the nonmagnetic metal between the first free layer and the second free layer, the atoms in the isolation coupling layer may cause interlayer charge transfer, so that the interlayer magnetic coupling is significantly enhanced, the magnetic anisotropy of the magnetic tunnel junction is enhanced, and the information writing capability of the corresponding device with the magnetic tunnel junction structure is further improved.

The above descriptions are only preferred embodiments of the present disclosure and are not intended to limit the present disclosure, and for those skilled in the art, the present disclosure may have various modifications and changes. Any modifications, equivalent replacements, or improvements, made within the spirit and principles of the present disclosure, shall fall within the protection scope of the present disclosure.

1. A magnetic tunnel junction structure, comprising a reference layer, a barrier layer and a free layer, which are stacked, wherein the free layer comprises:
a first free layer, disposed on a side of the barrier layer that is away from the reference layer, a material of the first free layer comprising a first cobalt-ferrum boride;
an isolation coupling layer, disposed on a side of the first free layer that is away from the barrier layer, a material of the isolation coupling layer comprising at least one nonmagnetic metal; and
a second free layer, disposed on a side of the isolation coupling layer that is away from the first free layer, a material of the second free layer comprising a second cobalt-ferrum boride, and the second cobalt-ferrum boride being doped with at least one nonmagnetic metal, or the first cobalt-ferrum boride being doped with at least one nonmagnetic metal, or the second cobalt-ferrum boride and the first cobalt-ferrum boride being doped with at least one nonmagnetic metal.

2. The magnetic tunnel junction structure according to claim 1, wherein the material of the isolation coupling layer comprises a first nonmagnetic metal, the first cobalt-ferrum boride is doped with a second nonmagnetic metal, and the second cobalt-ferrum boride is doped with a third nonmagnetic metal.

3. The magnetic tunnel junction structure according to claim 2, wherein a type of the second nonmagnetic metal is the same as a type of the third nonmagnetic metal.

4. The magnetic tunnel junction structure according to claim 3, wherein the type of the second nonmagnetic metal and the type of the third nonmagnetic metal are the same as a type of the first nonmagnetic metal.

5. The magnetic tunnel junction structure according to claim 2, wherein the first nonmagnetic metal, the second nonmagnetic metal and the third nonmagnetic metal independently comprise any one or more of hafnium, zirconium, tantalum, molybdenum, tungsten, iridium, ruthenium, rhodium, and magnesium.

6. The magnetic tunnel junction structure according to claim 2, wherein a doping concentration of the second nonmagnetic metal and a doping concentration of the third nonmagnetic metal independently satisfy 5%-25%.

7. The magnetic tunnel junction structure according to claim 6, wherein a doping concentration of the second nonmagnetic metal is equal to a doping concentration of the third nonmagnetic metal.

8. The magnetic tunnel junction structure according to claims 1, wherein a thickness of the isolation coupling layer is in a range of 0.2-2.0 Å.

9. The magnetic tunnel junction structure according to claims 1, wherein the magnetic tunnel junction structure comprises a plurality of groups of stacked structures, which are stacked, and each of group of stacked structures comprises one first free layer, one isolation coupling layer, and one second free layer.

10. The magnetic tunnel junction structure according to claims 1, wherein a thickness of the isolation coupling layer is greater than a thickness of the first free layer or a thickness of the second free layer.

11. The magnetic tunnel junction structure according to claim 9, wherein the material of the first free layer in each group of stacked structures is the first cobalt-ferrum boride or an alloy of the second nonmagnetic metal and the first cobalt-ferrum boride, and the material of the second free layer in each group of stacked structures is the second cobalt-ferrum boride or an alloy of the third nonmagnetic metal and the second cobalt-ferrum boride.

12. The magnetic tunnel junction structure according to claim 9, wherein the material of the first free layer in each group of stacked structures is the alloy of the second nonmagnetic metal and the first cobalt-ferrum boride, the material of the second free layer in each group of stacked structures is the alloy of the third nonmagnetic metal and the second cobalt-ferrum boride, a doping content of the second nonmagnetic metal in the first free layer is the same as a doping content of the third nonmagnetic metal in the second free layer.

13. The magnetic tunnel junction structure according to claim 9, wherein in each group of stacked structures, the material of the first free layer is the first cobalt-ferrum boride, the isolation coupling layer is a first nonmagnetic metal layer, the material of the second free layer is the second cobalt-ferrum boride, the first free layers and the second free layers in two adjacent layers of stacked structures together constitute the first free layer or the second free layer in each group of stacked structures.

14. The magnetic tunnel junction structure according to claim 1, wherein the magnetic tunnel junction structure comprises one first free layer, a plurality of isolation coupling layers and a plurality of second free layers, and the plurality of the isolation coupling layers and the plurality of the second free layers are alternately stacked to constitute a plurality of groups of stacked structures.

15. The magnetic tunnel junction structure according to claim 14, wherein the magnetic tunnel junction structure comprises one first free layer, one isolation coupling layer and the plurality of the groups of stacked structures, or the magnetic tunnel junction structure comprises one first free layer and the plurality of the groups of stacked structures.

16. The magnetic tunnel junction structure according to claim 14, wherein the number of the stacked structures is greater than or equal to 2 and less than or equal to 12.

17. The magnetic tunnel junction structure according to claim 1, wherein the magnetic tunnel junction structure comprises a plurality of first free layers, a plurality of isolation coupling layers and one second free layer, and the plurality of the first free layers and the plurality of the isolation coupling layers are alternately stacked to constitute a plurality of groups of stacked structures.

18. The magnetic tunnel junction structure according to claim 17, wherein the magnetic tunnel junction structure comprises the plurality of the groups of stacked structures, one isolation coupling layer and one second free layer, or the magnetic tunnel junction structure comprises the plurality of the groups of stacked structures and one second free layer.

19. The magnetic tunnel junction structure according to claim 17, wherein the number of the stacked structures is greater than or equal to 2 and less than or equal to 12.

20. The magnetic tunnel junction structure according to claim 1, wherein the magnetic tunnel junction structure comprises a plurality of first free layers, a plurality of isolation coupling layers and a plurality of second free layers, the plurality of the first free layers and the plurality of the isolation coupling layers are alternately stacked to constitute a plurality of groups of first alternating stacked structures, the plurality of the isolation coupling layers and the plurality of the second free layers are alternately stacked to constitute a plurality of groups of second alternating stacked structures, the number of the first alternating stacked structures is greater than or equal to 2 and less than or equal to 12, and the number of the second alternating stacked structures is greater than or equal to 3 and less than or equal to 12.
